(19) United States
(12) Patent Application Publication
(10) Pub. No.: US 2008/0191397 A1
(43) Pub. Date: Aug. 14, 2008

(54) Piezo-Hydraulic Linear Actuator For Vibration Control

(76) Inventor: Mario Biserni, Roma (IT)

Correspondence Address: LADAS & PARRY, 5670 WILSHIRE BOULEVARD, SUITE 2100, LOS ANGELES, CA, 90036-5679, US

(21) Appl. No.: 11/993,959

(22) PCT Filed: Jun. 28, 2006
(86) PCT No.: PCT/IT2006/000497

§ 371 Date: Apr. 10, 2008

(30) Foreign Application Priority Data
Jun. 28, 2005 (IT) RM2005A000339

(51) Int. Cl. F16F 15/02; H01L 41/09

(52) U.S. Cl. 267/75

(57) ABSTRACT

A piezo-hydraulic linear actuator (1) for controlling the vibrations through a piezoceramic element (7) that acts onto a proper liquid placed inside a cavity (3) (similar to a Helmholtz resonator configuration) by means of a flexible metallic membrane (8). The equipment whose vibrations must be controlled is fastened to a mobile plate (4) placed onto anyone of the cavity walls. The cavitation phenomena can be avoided by using two piezoceramic elements (7,9) acting onto the liquid in phase opposition one with respect the other one. The actuator can be designed to control the vibrations on one, two or three axes.

The invention refers to a new type of linear actuator based upon a piezo-hydraulic principle.

The actuator of the invention operates as a shifting amplifier, having a piezoceramic element acting on a proper liquid placed inside a cavity (similar to a Helmholtz resonator configuration) by means of a flexible metallic membrane.

A mobile plate, thereto the equipment is fastened, whose vibrations must be controlled, is placed onto anyone of the cavity walls.

By properly powering with voltage the piezoceramic element, the liquid inside the cavity is able to move the mobile plate with the desired motion rule.

The liquid type is chosen depending upon the design requirements which must be guaranteed in terms of thermal conductivity, viscosity, sound propagation speed, etc.

The cavitation phenomena can be avoided by using a configuration of the actuator, as it will be shown in the here illustrated description, which provides two piezoceramic elements acting onto the liquid in phase opposition one with respect the other one.

The actuator can be designed to exert the control of the vibrations on one, two or three axes.

### APPLICATION FIELDS

The present invention relates to the control of vibrations in general.

More specifically, its elective application is to control the vibrations of aerospace equipments in flight and during the launch.

The use of the actuator of the invention, properly integrated in an active system for controlling the vibrations, results to be very efficient not only to “isolate” delicate equipments from vibrations, but also for many other applications such as, for example, the control of microvibrations into orbit or the increasing stability of tracking systems.

In the aerospace field equipments, including also electronic units, are subjected to severe levels of mechanical vibrations, as i.e. vibro-acoustic stresses generated during the launch of a missile due to the atmospheric turbulences.

These vibrations can be classified into two groups depending upon the dynamic features thereof: a) Sinusoidal vibrations; b) Random vibrations.

Sinusoidal vibrations are low-frequency mechanical vibrations (typically below 100 Hz) produced by the response of the main structure of the aircraft or the missile to the dynamic loads.

Random vibrations, instead, are produced upon crossing the atmosphere by the turbulences of the atmosphere itself; on the outer surfaces they reveal as acoustic-pressing loads which transmit inside the structures as mechanical vibrations of random type.

The typical frequency band for these vibrations is comprised within 5 Hz and 2000 Hz.

Not always it is possible designing “delicate and sensible” equipments able to resist to vibrations during the flight of an aircraft or the launch of a missile. In these cases the sensible object has the possibility of flying in an adequate packaging or, if it has to be operated during the flight, the only solution is to isolate it as much as possible from the dynamic loads thereto it is subjected during the operation thereof.

Therefore, the active control of the vibrations becomes almost an obliged route to be followed.

The features which a linear actuator must have for controlling the vibrations are mainly the one indicated hereinafter:

i) high response speed (the random vibrations usually reach 2000 Hz);
ii) actuation preciseness in order to obtain very low residual accelerations;
iii) relatively high stroke (few millimetres);
iv) very reduced weight and volume.

Linear actuators utilizing a phase change (for example those with paraffin or those utilizing materials with shape memory) generate strong pushes, but they are very slow and the push control can result to be very complex and imprecise.

On the other side, piezoelectric actuators have high response speeds, high positioning preciseness and push control, but very low strokes (tens of μm).

### DESCRIPTION OF THE INVENTION

The actuator of the invention joins the features of both typologies and meets all of above requirements.

Therefore it is an object of the instant invention a piezo-hydraulic linear actuator composed by:
a hollow body suitable to be filled with a liquid;
at least one primary piezoelectric element connected to the body by means of at least one elastic membrane;
a primary mobile plate able to move along a direction under the liquid pressure.

Preferably the liquid includes some metals. In a preferred embodiment the mobile plate is constituted by a “piston-cylinder” system, alternatively by a bellows-like elastic member.

The piezo-hydraulic linear actuator of the invention can be integrated with an anti-cavitation system formed by:
a secondary piezoelectric element connected to the liquid by means of an elastic membrane;
a secondary mobile plate rigidly fastened to the primary plate;
   wherein piezoelectric elements are powered so as to make them to operate in phase opposition.

Alternatively, the piezo-hydraulic linear actuator of the invention can be integrated with an anti-cavitation system formed by:
a return spring with suitable stiffness mounted onto the mobile plate.

It is another object of the invention a system of piezo-hydraulic linear actuators composed by:
a main actuator according to claim 4 or 5;
a hollow structure of first level;
two equal actuators of first level according to claims 1 to 3 mounted on opposed sides of said hollow structure of first level;
a hollow structure of second level;
two equal actuators of second level according to claims 1 to 3 mounted onto the pair of opposed sides of said hollow structure of second level orthogonal to the pair of opposed sides of said hollow structure of first level whereon said actuators of first level are mounted.

### BRIEF DESCRIPTION OF THE DRAWINGS

The invention will be described in exemplificative not limiting embodiments by reference to the following figures.

FIG. 1 shows the linear actuator in its base configuration, that is operating on one single axis and without the anti-cavitation system, wherein the dotted lines relate to the situation of the powered and expanding piezoelectric element.

FIG. 2 shows the linear actuator with the anti-cavitation system in the control configuration on one single axis.

FIG. 3 shows the system of linear actuators able to control the mechanical vibrations on three axes without cavitation phenomena.

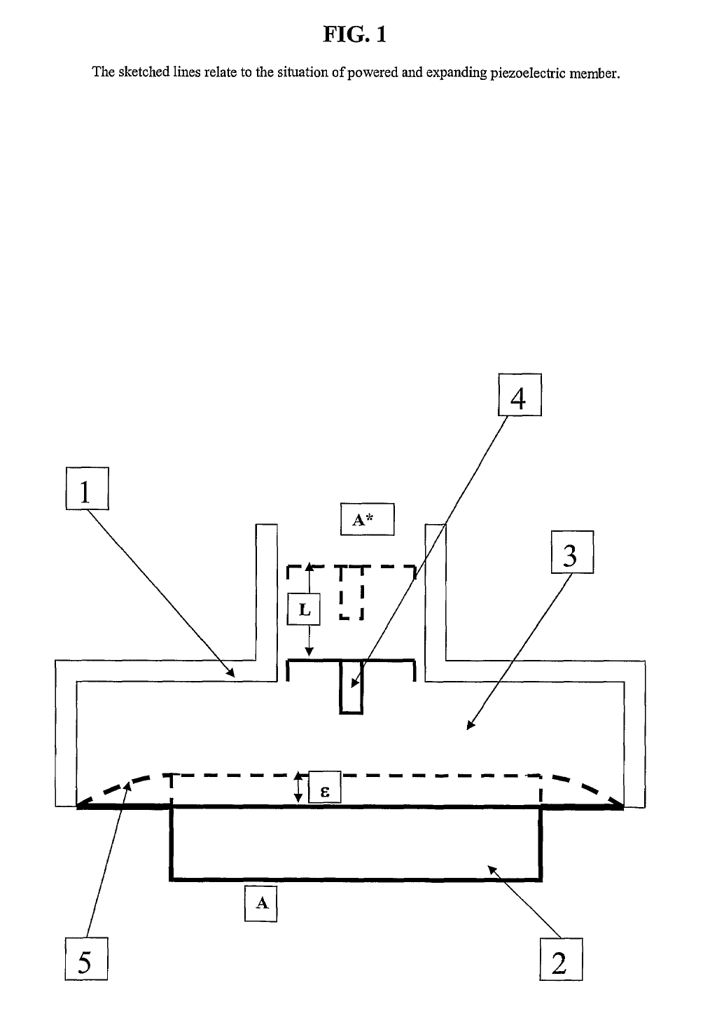

The actuator is based upon the stroke amplification which can be obtained by using a piezoelectric element as active material in a configuration similar to a Helmholtz resonator of the type shown in FIG. 1.

The inner volume V is filled-up with a proper liquid (also a liquid metal, for example) the features thereof must satisfy requirements of thermal conductivity, viscosity, sound propagation speed, etc.

The piezoelectric element expands or contracts depending upon the voltage applied to its clamps until a maximum stroke ε (some tens of μm) thus moving a liquid volume dV≅Aε with A the surface of the piezoelectric element.

The stroke L of the mobile plate (piston and bellows), the section thereof has surface A*, then L≅—Aε/A* results.

Then, the gain in stroke terms results of about: L/ε≅A/A*.

By assuming that the actuator behaves like a Helmholtz resonator, the liquid can be chosen, the piezoelectric element and the cavity can be sized so as to have a first resonance frequency higher than the extreme limit of the random vibrations (2000 Hz) and keep linear the dynamic behaviour of the system (having the unitary amplification from 0 to 2000 Hz is the best).

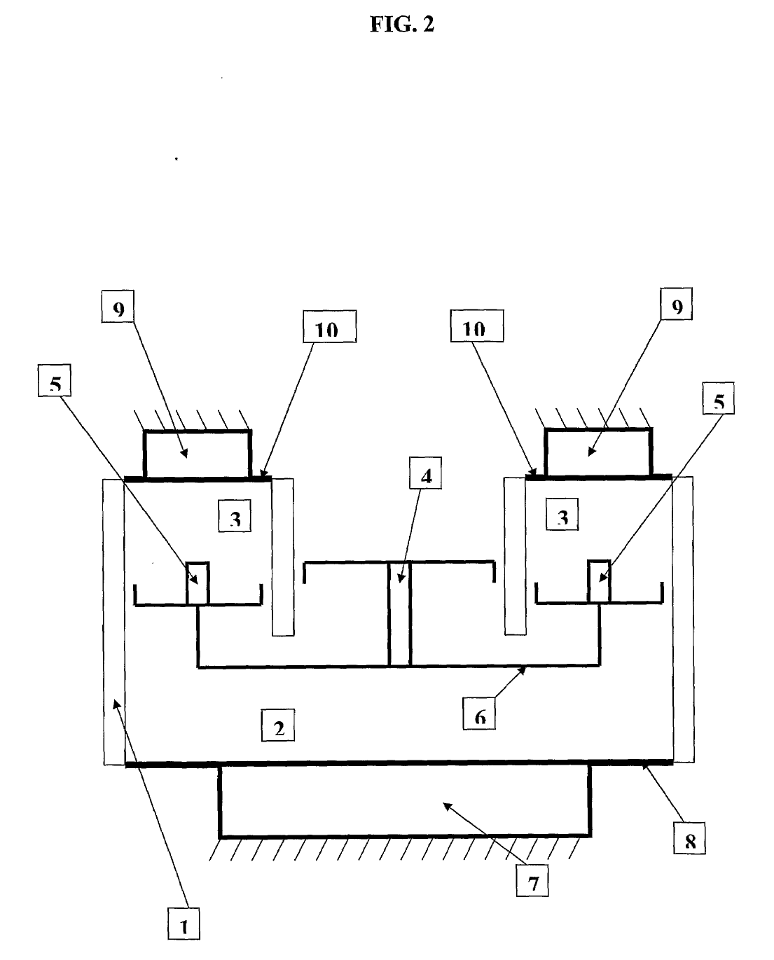

The cavitation phenomenon at the highest frequencies is avoided with a configuration of the actuator of the type shown in FIG. 2, wherein the two piezoelectric elements 7 and 9 (in figure the piezoelectric element 9 has an annular shape) operate in phase opposition; when one, upon expanding, pushes the liquid, the other one recalls the liquid into the cavity by contracting. In this way the liquid pressure in the two cavities (the cavity 2 and the cavity 3 with annular shape) remains almost unchanged also during the control of high-frequency vibrations.

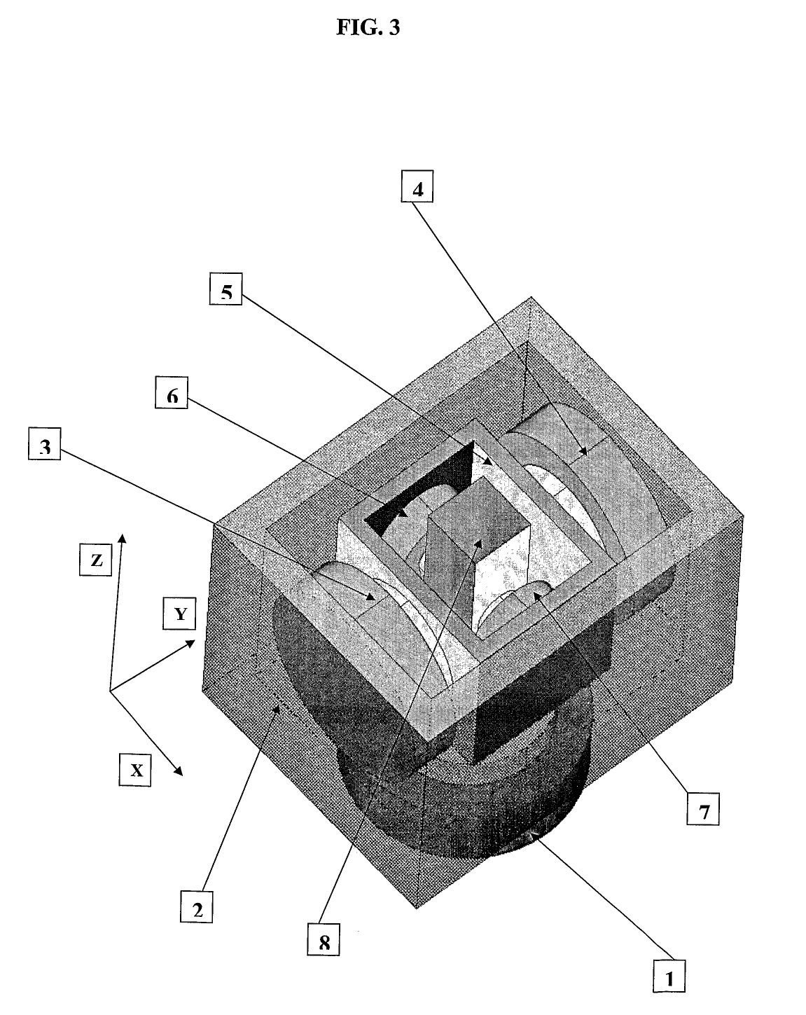

On the contrary, FIG. 3 shows the configuration of piezoelectric actuators able to control the mechanical vibrations on all three of the axes simultaneously. It consists in a linear actuator acting on an axis as the one of FIG. 2, on the mobile plate a stiff structure thereof is fastened, which has on the inside, on two surfaces opposed therebetween, two linear actuators as those of FIG. 1, which allow to control the vibrations on one of the other two axes by operating in phase opposition.

An additional stiff structure, similar to the previous one, is fastened to the plates of the last two actuators; two linear actuators of the type of FIG. 1 are fastened also inside this structure, on two opposite faces.

These last two actuators, by operating in phase opposition as well, allow to control the vibrations along the remaining axis.

### DETAILED DESCRIPTION OF THE INVENTION

FIG. 1 shows the operating concept diagram of the piezo-hydraulic linear actuator. The body of the actuator 1 bears on the inside thereof a sealed cavity 3 full of liquid. A body wall is equipped with an opening which puts into communication the cavity full of liquid 3 with the mobile plate 4, whether it is a simple piston able to slide into a cylinder obtained in the body 1 itself or a bellows-like member made of suitable material. A cavity wall is constituted by a flexible membrane 5 thereto the piezoelectric element 2 is rigidly fastened.

When the piezoelectric element 2 is powered with positive voltage, the latter expands by a length ε by compressing the liquid inside the cavity 3 against the mobile plate 4 which, in turn, moves by the length L.

If the voltage power supply of the piezoelectric element 2 is produced as response of a suitable electronic system in feedback to a sensor of mechanical vibrations (for example an accelerometer), the piezo-hydraulic linear actuator as shown in FIG. 1 is able to control the mechanical vibrations transmitted to a sensible equipment fastened to the mobile plate 4 for relatively low vibration frequencies, that is below the liquid cavitation threshold.

FIG. 2 schematizes the configuration of the piezo-hydraulic actuator with the anti-cavitation system.

The body of the actuator 1 has on the inside thereof a sealed cavity 2 full of liquid. A body wall is equipped with an opening which puts into communication the cavity full of liquid 2 with the primary mobile plate 4 and with the secondary annular mobile plate 5, whether they are simple pistons able to slide into the respective cylinders obtained in the body 1 itself or bellows-like members made of a suitable material. The mobile plates 4 and 5 are rigidly connected by means of the stiff member 6. A cavity wall is constituted by a flexible membrane 8 thereto the primary piezoelectric element 7 is rigidly fastened. The annular wall 10 too, at the secondary plate 5, is constituted by a flexible membrane thereto the secondary piezoelectric element 9 with annular shape is rigidly fastened.

The primary piezoelectric element 7 and the secondary one 9 can expand and contract by the same Volume dV and the mobile plates, the primary one 4 and the secondary one 5, with parity of volume of moved liquid, move in expansion or in contraction by the same motion ε. When the primary piezoelectric element 7 is powered with voltage variable in time Vₚ(t), the secondary piezoelectric element 9 must be powered with voltage −Vₛ(t) so that in each instant there is εₚ=−εₛ that is to the expansion of a piezoelectric element, for example the primary one 7, corresponds the compression of the other one, for example the secondary one 9.

In this way, the whole liquid volume inside the two cavities, the primary cavity 2 and the secondary one 3, is able to move by keeping almost constant the pressure inside thereof with the result of not having cavitation phenomena in the liquid.

The so-conceived linear actuator, that is with the anti-cavitation system, allows to control the vibration onto one single axis for mechanical, also high-frequency vibrations.

FIG. 3 shows the system of linear actuators implementing the control of vibration onto three axes.

A hollow structure of first level 2 is fastened to the primary mobile plate of a linear actuator like the one of FIG. 2, the main actuator 1, that is with the integrated anti-cavitation system. The hollow structure of first level 2 bears on the inside thereof the two linear actuators of first level 3 and 4, mounted on opposed sides, which are actuators without anti-cavitation system (like the one of FIG. 1), but which, as they operate in phase opposition, form an anti-cavitation pair on the conceptual model of the actuator of FIG. 2.

The hollow structure of second level 5 similar to 2 is fastened to the two mobile plates of the actuators of first level 3 and 4, which structure bears on the inside thereof the two actuators of second level 6 and 7, which are of the same type of those of first level 3 and 4, but mounted on two sides orthogonal to the sides of the hollow structure of first level 2 which bear the actuators of first level 3 and 4.

At last, the mechanical interface 8, with the equipment the vibrations thereof are wanted to be controlled, is fastened to the mobile plates of the actuators of second level 6 and 7.

By assuming that the term of reference axes be oriented like the one of the figure, the actuator 1 allows to control the vibrations along the axis Z, the actuators 3 and 4 along the axis Y and the actuators 6 and 7 control the vibrations onto the axis X.

1. Piezo-hydraulic linear actuator composed by:
a hollow body suitable to be filled with a liquid;
at least one primary piezoelectric element connected to the body by means of at least one elastic membrane;
a primary mobile plate able to move along a direction under the liquid pressure.

2. Piezo-hydraulic linear actuator according to claim 1 wherein the liquid includes some metals.

3. Piezo-hydraulic linear actuator according to claim 1 wherein the mobile plate is constituted by a “piston-cylinder” system or by a bellows-like elastic member.

4. Piezo-hydraulic linear actuator according to claim 1 being integrated with an anti-cavitation system formed by:
a secondary piezoelectric element connected to the liquid by means of an elastic membrane;
a secondary mobile plate rigidly fastened to the primary plate;
wherein piezoelectric elements are powered so as to make them to operate in phase opposition.

5. Piezo-hydraulic linear actuator according to claim 1 being integrated with an anti-cavitation system formed by:
a return spring with suitable stiffness mounted onto the mobile plate.

6. System of piezo-hydraulic linear actuators composed by:
a main actuator according to claim 4;
a hollow structure of first level;
two equal actuators of first level mounted on opposed sides of said hollow structure of first level;
a hollow structure of second level;
two equal actuators of second level mounted onto the pair of opposed sides of said hollow structure of second level orthogonal to the pair of opposed sides of said hollow structure of first level whereon said actuators of first level are mounted.
